(19) United States
(12) Patent Application Publication
(10) Pub. No.: US 2020/0118864 A1
(43) Pub. Date: Apr. 16, 2020

(54) HANDLING APPARATUS AND HANDLING METHOD THEREFOR

(71) Applicant: SHANGHAI MICRO ELECTRONICS EQUIPMENT (GROUP) CO., LTD., Shanghai (CN)

(72) Inventors: Yudi ZHANG, Shanghai (CN); Jing ZHEN, Shanghai (CN)

(21) Appl. No.: 16/618,314

(22) PCT Filed: May 30, 2018
(86) PCT No.: PCT/CN2018/089071

§ 371 Date: Nov. 29, 2019

(30) Foreign Application Priority Data
May 31, 2017 (CN) 201710400604.9

(51) Int. Cl. H01L 21/687; H01L 21/677; H01L 21/67

(52) U.S. Cl. CPC H01L 21/68707; H01L 21/6773; H01L 21/67706; H01L 21/67294; H01L 21/67724

(57) ABSTRACT

A handling apparatus and handling methods thereof. The handling apparatus includes a movable transport mechanism; support platform having a support surface parallel to a horizontal plane, configured to support objects to be handled, a plurality of loading stations being circumferentially defined on the support surface to receive the objects to be handled, the support platform defining a through hole at a center thereof gripping mechanism, configured to pick and place the objects to be handled, the gripping mechanism having one end traversing through the through hole and being connected to the transport mechanism; and driving mechanism, configured to drive the support platform to rotate in the horizontal plane above the transport mechanism. The handling apparatus and methods enable the gripping mechanism to follow a same travel path to pick up objects from the target place for picking or placing, thus enhancing efficiency of the handling apparatus.

### TECHNICAL FIELD

The present invention relates to the technical field of semiconductor manufacturing and, more specifically, to a handling apparatus and a handling method thereof.

### BACKGROUND

Nowadays, semiconductor manufacturers in the world generally use handling apparatuses to handle wafer cassettes in place of conventional manual operation. In particular, techniques for handling 8-inch wafer cassettes are more and more mature, while those for 12-inch wafer cassettes are not common. Most existing apparatuses for this purpose are automated guided vehicles (AGVs) equipped with a robotic arm controlled to handle wafer cassettes based on vision measurements after the AGV arrives at a specified location.

FIG. 1 schematically shows a handling apparatus with a robotic arm located at a high position, and FIG. 2 is a graph showing a gravity center profile of the robotic arm during its operation. FIG. 3 shows another handling apparatus with a robotic arm located at a low position. In FIG. 1, the robotic arm 103 is mounted above the position at which a plurality of wafer cassettes 101 are loaded directly above one another. Specifically, the robotic arm 103 is provided at one end with a gripper 102 which can lift a wafer cassette 101 by horizontally gripping its side ears or top flange for transportation. However, since the center of gravity of the robotic arm 103 is at a high position, the handling apparatus is likely to tip over. Moreover, limited to a maximum payload of the robotic arm 103, an overload safety mechanism in the handling apparatus is often triggered when it attempts to pick up a fully-loaded 12-inch wafer cassette. FIG. 2 shows a gravity center profile of the robotic arm 103 of FIG. 1, in which the horizontal axis represents the displacement of the gravity center of the robotic arm, measured in millimeters (mm), and the vertical axis represents the height of the gravity center relative to the ground surface, also measured in mm. When the robotic arm grips and lifts a wafer cassette, the robotic arm's gravity center is at a position shown by the point B in the figure. As the robotic arm pivots to the left or right, the robotic arm's gravity center will accordingly shift between point B and point A or between point B and point C.

In FIG. 3, the robotic arm 203 is mounted at a side below a position at which a plurality of wafer cassettes 101 are loaded directly above one another. Specifically, the robotic arm 203 is provided at one end with a gripper 202 which can grip a wafer cassette 101 at its side ears or top flange for transportation. The robotic arm 203 is designed with a long, complicated travel path. When the robotic arm 203 moves to a certain position, a sudden acceleration will occur. As a result, the handling apparatus is likely to be shut down. Additionally, in order to avoid interference between the robotic arm 203 and a frame (not shown) in the operation of picking and placing a wafer cassette, a large number of additional collision avoidance paths have to be designed for the gripper 202 at the expense of compromised handling efficiency.

Further, both the above apparatuses have a low capacity permitting the handling of at most only two wafer cassettes in a single trip and are approaching their limit with the increasing use of 12-inch wafer cassettes. Therefore, it is necessary to develop a handling apparatus with a small footprint, a great capacity, a versatile travel path and high efficiency and corresponding handling methods.

### SUMMARY OF THE DISCLOSURE

An objective of the present invention is to overcome one or more of the above problems in the prior art, i.e., low wafer cassette handling efficiency, a low handling capacity per trip and low stability, by providing a handling apparatus and handling methods.

To achieve the objective, the present invention provides a handling apparatus, comprising: a movable transport mechanism; a support platform having a support surface parallel to a horizontal plane, the support surface being configured to support objects to be handled, a plurality of loading stations being circumferentially defined on the support surface to receive the objects to be handled, the support platform defining a through hole at a center thereof; a gripping mechanism, configured to pick and place the objects to be handled, the gripping mechanism having one end traversing through the through hole and being connected to the transport mechanism; and a driving mechanism, configured to drive the support platform to rotate in the horizontal plane above the transport mechanism.

Optionally, the transport mechanism comprises an automated guided vehicle.

Optionally, the transport mechanism further comprises a caster-equipped support frame disposed over the automated guided vehicle to support the support platform, the driving mechanism and the gripping mechanism.

Optionally, the support platform is in a form of a circular disc.

Optionally, the loading stations are provided with locating mechanisms matching and connectable with the objects to be handled.

Optionally, the driving mechanism comprises a transmission mechanism and a driving motor connected to the transmission mechanism, the transmission mechanism is connected to the support platform, and configured to rotate the support platform under an action of the driving motor.

Optionally, the transmission mechanism comprises a driving gear and a driven gear, the driving gear is coupled to a driving shaft of the driving motor, and the support platform is secured to the driven gear.

Optionally, the driving gear is engaged with the driven gear through contacting each other or using a chain.

Optionally, the handling apparatus further comprises a control mechanism connected to each of the transport mechanism, the gripping mechanism and the driving mechanism, the control mechanism configured to control a rotation of the support platform, a movement of the transport mechanism and an operation of the gripping mechanism.

Optionally, the control mechanism comprises a sensor mounted at a tail end of the gripping mechanism and is configured to confirm whether one of the loading stations is loaded with a corresponding one of the objects to be handled and control, based on results of the confirmation, the rotation of the support platform.

Optionally, the objects to be handled are wafer cassettes.

The present invention also provides a handling method comprising: moving a transport mechanism to an object storage place; driving, by a driving mechanism, a support platform to rotate in a horizontal plane to allow one of a plurality of loading stations that is loaded with an object to be handled to move to a location facing the object storage place; picking up the object from the loading station and placing the object at the object storage place, by a gripping mechanism; and repeating the above steps to successively transport objects to be handled from the plurality of loading stations to the object storage place.

The present invention also provides a handling method comprising: moving a transport mechanism to an object storage place; driving, by a driving mechanism, a support platform to rotate in a horizontal plane to allow one of a plurality of loading stations that is loaded with an object to be handled to move to a location facing the object storage place; picking up the object from the object storage place and placing the object at the loading station, by a gripping mechanism; and repeating the above steps to successively transport objects to be handled to the plurality of loading stations.

Optionally, the objects to be handled are wafer cassettes, each of the loading stations is provided with an identification device for identifying an identification mark on a wafer cassette, and when the handling apparatus moves to the object storage place while carrying a target one of the wafer cassettes, one of the loading stations loaded with the target one of the wafer cassettes is identified based on information fed back from the identification device and the driving mechanism drives the support platform to rotate in the horizontal plane so that the loading station loaded with the target one of the wafer cassettes is moved to the place facing the object storage place.

In summary, according to the handling apparatus and methods thereof provided in the present invention, a plurality of loading stations are defined circumferentially on the support surface of the support platform and each of the loading stations is configured to receive an object to be handled, the driving mechanism is configured to drive the support platform to rotate so that the one of the stations at which a target object to be handled is placed are shifted to a target place for picking or placing, and the gripping mechanism has an end traversing through the through hole formed at the center of the support platform and is connected to the transport mechanism. In this way, it is possible for the gripping mechanism to follow a same travel path for each time in gripping the object placed at the target place for picking or placing, thereby enhancing efficiency of the handling apparatus. Compared with a design where multiple loading stations are arranged vertically one above another, the above design is advantageous in a shorter, simpler travel path of the gripping mechanism, no need for designing additional paths for avoiding interference, simpler control, higher handling efficiency, more than two wafer cassettes handled in each trip and a higher overall handling capacity.

### BRIEF DESCRIPTION OF THE DRAWINGS

FIG. 1 schematically shows a handling apparatus with a robotic arm located at a high position.

FIG. 2 is a graph showing a gravity center profile of the robotic arm of FIG. 1

FIG. 3 schematically shows a handling apparatus with a robotic arm located at a low position.

FIG. 4 is a structural schematic of a handling apparatus according to an embodiment of the present invention when it is loaded with wafer cassettes.

FIG. 5 is a structural schematic of the handling apparatus of FIG. 4 during its wafer cassette loading/unloading operation.

FIG. 6 is a structural schematic of a handling apparatus according to another embodiment of the present invention when it is loaded with wafer cassettes.

FIG. 7 is a top view of the handling apparatus of FIG. 6 when a support platform is removed therefrom.

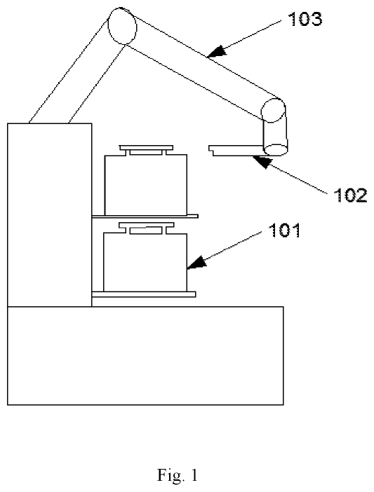

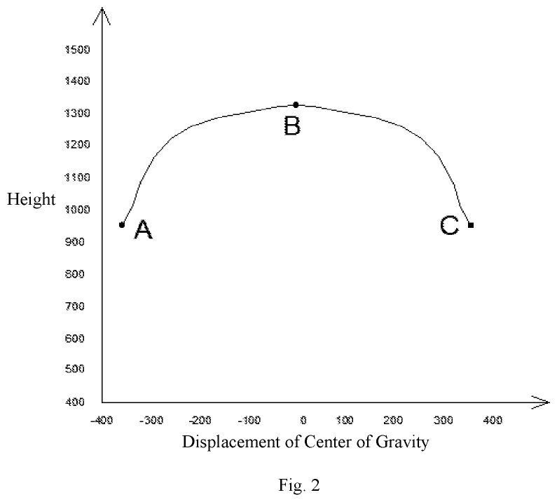

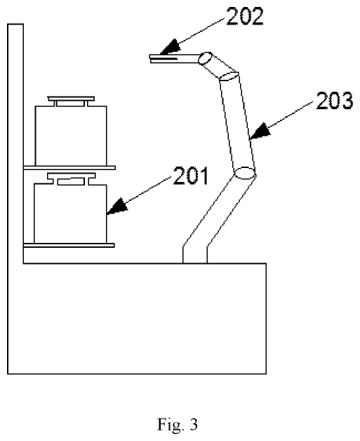

### LIST OF REFERENCE NUMERALS IN THE DRAWINGS

101, 201 Wafer Cassette
102, 202 Gripper
103, 203 Robotic Arm
10 Transport Mechanism
20 Support Platform
30 Driving Mechanism
40 Gripping Mechanism
301 Caster
302 Automated Guided Vehicle (AGV)
304 Wafer Cassette
305 Holder
306 Gripper
307 Robotic Arm
308 Transmission Mechanism
309 Driving Motor
310 Control Box
311 Locating Stud
401 First Shelf Location
402 Second Shelf Location
403 Third Shelf Location
404 Fourth Shelf Location
405 First Loading Station
406 Second Loading Station
407 Third Loading Station
408 Fourth Loading Station
501 Chain

### DETAILED DESCRIPTION

Specific embodiments of the present invention will be described in greater detail below with reference to the accompanying drawings. Features and advantages of the invention will be more apparent from the following detailed description, and from the appended claims. Note that the drawings are provided in a very simplified form not necessarily drawn to scale, and their only intention is to facilitate convenience and clarity in explaining the embodiments.

In the following, for the sake of simplicity, the structure and operation of a handling apparatus according to the present invention will be descried in detail in the context of handling wafer cassettes as an illustrative example.

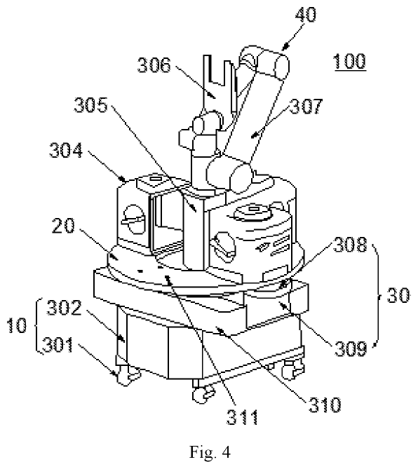

FIG. 4 is a structural illustration of a handling apparatus 100 according to an embodiment of the present invention. As shown in FIG. 4, the handling apparatus 100 includes a movable transport mechanism 10, a gripping mechanism 40, a support platform 20 and a driving mechanism 30.

Specifically, the driving mechanism 30 is configured to drive the support platform 20 to horizontally rotate above the transport mechanism 10. The support platform 20 has a support surface parallel to a horizontal plane, on which a plurality of loading stations are circumferentially defined to receive wafer cassettes 304. A through hole is formed at a center of the support platform 20. The gripping mechanism 40 is configured to pick or place the wafer cassettes 304. Additionally, gripping mechanism 40 has an end traversing through the through hole and is connected to the transport mechanism 10. The driving mechanism 30 is configured to drive the support platform 20 to horizontally rotate so that a target one of the loading stations is shifted to a target place for picking or placing to enable the gripping mechanism 40 to pick or place a wafer cassette 304.

In the handling apparatus according to this embodiment, a plurality of loading stations are defined circumferentially on the support surface of the support platform, and the plurality of loading stations are configured to receive the objects to be handled, and the driving mechanism is configured to drive the support platform to rotate so that the loading station on which a target one of the objects is placed is shifted to a target place for picking or placing. Additionally, the gripping mechanism has an end traversing through the through hole defined at the center of the support platform and is connected to the transport mechanism. In this way, it is possible for the gripping mechanism to follow a same travel path for each time in gripping the object placed at the target place for picking or placing, thereby enhancing efficiency of the handling apparatus.

Further, the transport mechanism 10 may include an automated guided vehicle (AGV) 302 and a caster-equipped support frame disposed over the AGV 302 to support the support platform 20, driving mechanism 30 and gripping mechanism 40. The transport mechanism 10 may further comprises casters 301 which are mounted on the AGV 302 to enable movement thereof. The driving mechanism 30 may include a transmission mechanism 308 and a driving motor 309. The transmission mechanism 308 may be connected to both the driving motor 309 and support platform 20 and configured to rotate the support platform 20 under the action of the driving motor 309.

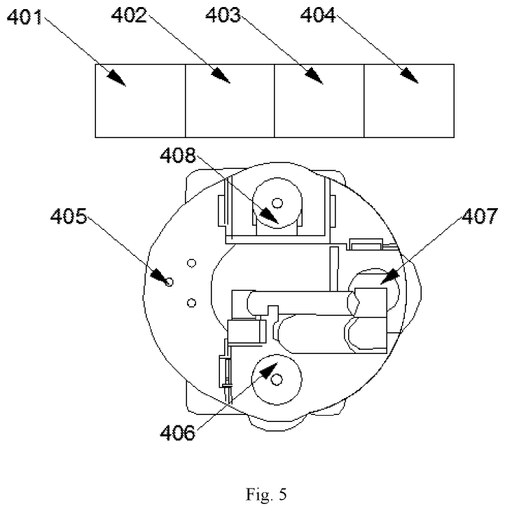

In this embodiment, the gripping mechanism 40 may include a holder 305 and a gripper 306. The gripper 306 may be disposed at one end of a robotic arm 307. The handling apparatus 100 may further include an electrical box 310 housing control mechanisms. The gripper may be provided with a sensor for controlling the rotation of the support platform by detecting an occupation status of the first loading station 405 as shown in FIG. 5 as well as an occupation status of each loading location of a target shelf.

With continued reference to FIG. 4, the AGV 302 may move with the support of the casters 301 to approach the target shelf. Preferably, the number of the casters 301 is four, and they are arranged in two rows on a bottom side of the AGV 302. The four casters 301 can facilitate stable movement of the AGV 302.

The support platform 20 may be in the form of a circular disc, and the through hole is preferred to be a round hole. Preferably, a plurality of sets of loading stations may be defined on the support surface of the support platform, and each set may include a plurality of loading stations arranged on a single circle. In addition, the plurality of sets may be arranged on different circles, so that the gripping mechanism can follow a single travel path to pick up wafer cassettes loaded on the same circle.

Preferably, each set may include four loading stations that are distributed in symmetry. By defining a plurality of loading stations, the handling apparatus 100 can be utilized more efficiently. The number of the loading stations may be determined as actually required, in order to achieve a higher handling capacity per trip and enhanced handling efficiency. Further, the symmetric arrangement of the stations enables more stable movement of the AGV 302.

Furthermore, each of the loading stations may be provided with a locating mechanism that can be matched with and connected to the object to be handled. Specifically, the locating mechanism may comprise a locating stud 311 configured to locate the wafer cassette 304 and a locating hole that can mate with the locating studs. Preferably, each of the loading stations may be provided with a plurality of, for example, three, such locating studs 311, that are not arranged on a straight line, more preferably, into a regular polygon such as a regular triangle. This arrangement of the locating studs allows the wafer cassette to be better fixed and prevented from falling off. It is a matter of course that the same number of the locating holes can be provided as that of the locating studs.

In one embodiment, the transmission mechanism 308 may include a driven gear and a driving gear engaging the driven gear. The driving gear may be coupled to a driving shaft of the driving motor 309, and the support platform 20 may be secured to the driven gear. In this way, the driving gear may rotate under the drive of the driving motor 309, causing the driven gear and hence the support platform secured thereto to rotate. Specifically, the support platform 20 may be attached to an outer peripheral surface of the driven gear, while the driven gear may be mounted on the AGV 302.

In this embodiment, a head end of the robotic arm 307 is equipped with the holder 305 which is mounted to a top surface of the AGV 302 through the through hole. Preferably, the holder 305 may be mounted to a center of the top surface of the AGV 302, so that the AGV 302 will stand steadily and will not be liable to tip over when the gripping mechanism 40 is picking up a wafer cassette 304. The robotic arm 307 may be connected to the holder 302 and may perform a pick-and-place action under the action of the driving mechanism 30.

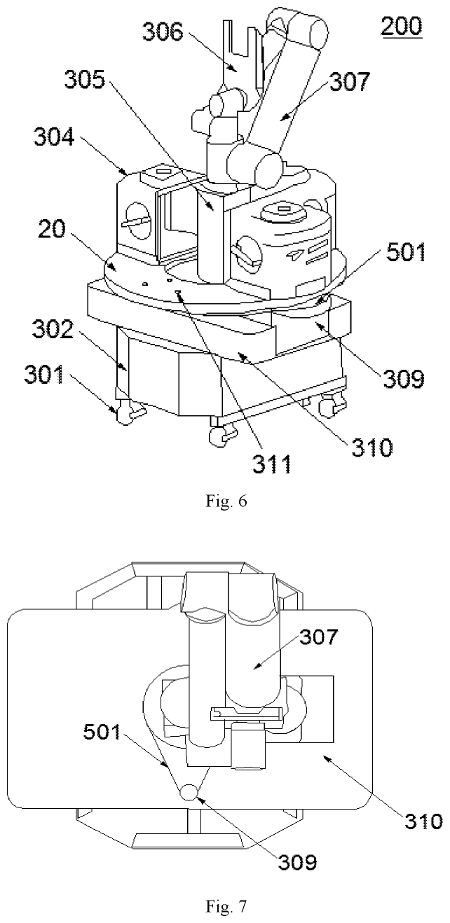

FIGS. 6 and 7 depict another embodiment of the present invention. FIG. 6 is a structural schematic showing a handling apparatus 200 according to the embodiment when it is loaded with wafer cassettes 304, while FIG. 7 is a top view of the handling apparatus 200 of FIG. 6 when a support platform is removed therefrom.

As shown in FIGS. 6 and 7, the handling apparatus 200 differs from the handling apparatus 100 in that the engagement between the driving gear and the driven gear is accomplished by a chain 501. In this case, the driving gear is coupled to a driving shaft of the driving motor 309, and the support platform 20 is secured to the driven gear. In this way, the driving gear can rotate under the drive of the driving motor 309, thus driving the driven gear to rotate via the chain 501. The rotation of the driven gear further causes the support platform secured thereto to rotate. Reference can be made to the description of the above embodiment for details in how a wafer cassette is loaded to or unloaded from the handling apparatus 200, and a detailed description thereof will be repeated here. This embodiment provides an alternative structure of the transmission mechanism 308 so that multiple options can be provided to address practical applications in a more flexible way, making the handling apparatus more suitable for actual fabrication.

Each of the handling apparatus 100 and the handling apparatus 200 may further comprise a control mechanism connected to each of the transport mechanism 10, the gripping mechanism 40 and the driving mechanism 30 and configured to control the rotation of the support platform 20, movement of the transport mechanism 10 and operation of the gripping mechanism 40. The control mechanism may include a sensor which is disposed at a tail end of the robotic arm and is configured to detect an occupation status of a certain one of the loading stations and control, based on the detected occupation status, the rotation of the support platform. The control mechanism may be implemented as a control box 310 such as a PCL controller, a host controller or the like, and those skilled in the art will know how to implement it from the disclosure herein. For example, the control box 310 may control the gripping mechanism 40 to pick up a wafer cassette. Wafers that can be handled by the handling apparatuses of the present invention include but are not limited to 8- and 12-inch wafers.

FIG. 5 is a structural schematic of the handling apparatus 100 of FIG. 4 during the process of loading/unloading a wafer cassette. As shown in FIG. 5, the loading/unloading process may involve the first shelf location 401, second shelf location 402, third shelf location 403 and fourth shelf location 404 and the first loading station 405, second loading station 406, third loading station 407 and fourth loading station 408. However, according to the present invention, the number of stations is not limited to four and may be determined as practically required. The wafer cassette loading and unloading processes performed by the handling apparatus 100 will be described below in detail with reference to FIGS. 4 and 5.

The unloading process may include:

Step 1, the transport mechanism 10 moving to the first shelf location 401 under the control of the control box 310;

Step 2, the control box 310 determining, based on detected information, whether a wafer cassette is present at the first loading station 405 and whether the gripping mechanism 40 is in a normal state, if both so, activating the gripping mechanism 40; and

Step 3, the activated gripping mechanism 30 picking up the wafer cassette from the first loading station 405 and placing it at the first shelf location 401.

In step 2, if the control box 310 determines, based on the detected information, that the first loading station 405 is unoccupied (i.e., no wafer cassette is placed thereon), the driving mechanism 30 may drive the support platform 20 to rotate so that a second loading station 406 is shifted to the position at which the first loading station 405 is placed before the shifting. Then, the control box 310 may again determine an occupation status of the second loading station 406 based on new detected information. This process may be repeated until it is found that a wafer cassette is placed at a certain one of the loading stations, and then the process of unloading wafer cassettes is continued. If the control box 310 determines, based on detected information, that no wafer cassette is placed on each of the stations, it may raise an alarm to alert an abnormality.

Subsequent to steps 1 to 3, the control box 310 may further control the transport mechanism 10 to move to the next shelf location so that steps 2 and 3 are performed for another time. This process may be repeated until all the wafer cassettes are unloaded and transported onto different shelf locations, thereby achieving the goal of unloading all the wafer cassettes from the handling apparatus 100 onto the target shelf.

Further, after the process of unloading and transporting all the wafer cassettes from the handling apparatus 100 onto the shelf is completed, the control box 310 detects the occupation statuses of all the loading stations to confirm whether all the wafer cassettes have been unloaded. If it is confirmed that all the wafer cassettes have been unloaded, the handling apparatus 100 may stand by and wait for a new task.

In another embodiment, each of the loading stations may be provided with an identification device for identifying an identification mark on a wafer cassette. In step 2, the control box 310 may identify the one of the loading stations where a target wafer cassette is loaded, based on information fed back from the identification device. Additionally, the control box 310 may further determine whether the identified loading station is located at the position at which the first loading station 405 is placed. If not, the control box 310 may control the driving mechanism to drive the support platform to horizontally rotate so that the loading station loaded with the target wafer cassette is shifted to the position at which the first loading station 405 is placed.

The process of loading the wafer cassettes onto the handling apparatus 100 may include:

Step 11, the transport mechanism 10 moving to the first shelf location 401 under the control of the control box 310;

Step 21, the control box 310 determining, based on detected information, whether the first loading station 405 is unoccupied and whether the gripping mechanism 40 is in a normal state, if both so, activating the gripping mechanism 40; and

Step 31, the gripping mechanism 40 picking up a wafer cassette from the first shelf location 401 and placing it at the first loading station 405.

In step 21, if the control box 310 determines, based on the detected information, that the first loading station 405 is occupied (i.e., a wafer cassette is placed thereon), the driving mechanism 30 may drive the support platform 20 to rotate so that a second loading station 406 is shifted to the position at which the first loading station 405 is placed before the shifting. Then, the control box 310 may again determine an occupation status of the second loading station 406 based on new detected information. This process may be repeated until a certain one of the loading stations is found unoccupied, and then the process of loading wafer cassettes is continued. If the control box 310 finds, based on detected information, that all of the loading stations are occupied (i.e., the apparatus is fully loaded), it may raise an alarm to alert an abnormality.

Subsequent to steps 11 to 31, the control box 310 may further control the transport mechanism 10 to move to the next shelf location so that steps 21 and 31 are performed for another time. This process may be repeated so that all wafer cassettes on the shelf may be transported and loaded to different loading stations, thereby achieving the goal of loading all the wafer cassettes from the target shelf onto the corresponding loading locations.

Further, after the process of loading all the wafer cassettes onto the handling apparatus 100 is completed, the control box 310 detects the occupation statuses of all the loading stations to confirm whether all the loading stations have been loaded with the wafer cassettes. If it is determined that all the loading stations have been loaded with the wafer cassettes, the handling apparatus 100 may stand by and wait for a new task.

Each of the above-described loading and unloading processes can be performed in an automated manner in which the control box 310 controls the other components based on a control program introduced into the control box 310 in advance by an operator at the beginning of the process.

In the steps of the above loading and unloading processes, when the first loading station 401 is loaded with a wafer cassette, it means that the first loading station 401 is occupied. The determination of whether the gripping mechanism 40 is in a normal state can be accomplished by checking its relevant operational parameters with the control mechanism prior to its activation. If the operational parameters are all normal, then the process can be continued. Otherwise, an alarm can be given.

In the apparatus and method according to this embodiment, by defining, on the support surface of the rotatable support platform, at least one set of loading stations that are located on a single circle and each configured to receive one wafer cassette, and through connecting the head end of the robotic arm in the gripping mechanism to the transport mechanism via the through hole in the support surface, the robotic arm is enabled to follow a same travel path to pick up wafer cassettes from the corresponding place, thus enhancing efficiency of the handling apparatus.

In summary, a plurality of loading stations are defined circumferentially on the support surface of the support platform and each of the loading stations is configured to receive an object to be handled, the driving mechanism is configured to drive the support platform to rotate so that the one of the stations at which a target object to be handled is placed are shifted to a target place for picking or placing, and the gripping mechanism has an end traversing through the through hole formed at the center of the support platform and is connected to the transport mechanism. In this way, it is possible for the gripping mechanism to follow a same travel path for each time in gripping the object placed at the target place for picking or placing, thereby enhancing efficiency of the handling apparatus. Compared with a design where multiple loading stations are arranged vertically one above another, the above design is advantageous in a shorter, simpler travel path of the gripping mechanism, absence of abrupt acceleration of the robotic arm, no need for design additional paths for avoiding interference, simpler control, higher handling efficiency, more than two wafer cassettes handled in each trip and a higher overall handling capacity.

In addition, since the gripping mechanism is mounted at the center of the AGV's top surface, the handling apparatus will stand steadily and will not be liable to tip over when the gripping mechanism is picking up a wafer cassette.

The embodiments presented above are merely several preferred examples and are in no way meant to limit the present invention. It is intended that any modifications such as equivalent alternatives or variations made to the subject matter or features thereof disclosed herein made by any person of ordinary skill in the art based on the above teachings without departing from the scope of the present invention are also considered to fall within the scope of the present invention.

1. A handling apparatus, comprising:
a movable transport mechanism;
a support platform having a support surface parallel to a horizontal plane, the support surface being configured to support objects to be handled, a plurality of loading stations being circumferentially defined on the support surface to receive the objects to be handled, the support platform defining a through hole at a center thereof;
a gripping mechanism, configured to pick and place the objects to be handled, the gripping mechanism having one end traversing through the through hole and being connected to the transport mechanism; and
a driving mechanism, configured to drive the support platform to rotate in the horizontal plane above the transport mechanism.

2. The handling apparatus of claim 1, wherein the transport mechanism comprises an automated guided vehicle.

3. The handling apparatus of claim 2, wherein the transport mechanism further comprises a caster-equipped support frame disposed over the automated guided vehicle to support the support platform, the driving mechanism and the gripping mechanism.

4. The handling apparatus of claim 1, wherein the support platform is in a form of a circular disc.

5. The handling apparatus of claim 1, wherein the loading stations are provided with locating mechanisms matching and connectable with the objects to be handled.

6. The handling apparatus of claim 1, wherein the driving mechanism comprises a transmission mechanism and a driving motor connected to the transmission mechanism, the transmission mechanism is connected to the support platform, and configured to rotate the support platform under an action of the driving motor.

7. The handling apparatus of claim 6, wherein the transmission mechanism comprises a driving gear and a driven gear, the driving gear is coupled to a driving shaft of the driving motor, and the support platform is secured to the driven gear.

8. The handling apparatus of claim 6, wherein the driving gear is engaged with the driven gear through contacting each other or using a chain.

9. The handling apparatus of claim 1, further comprising a control mechanism connected to each of the transport mechanism, the gripping mechanism and the driving mechanism, the control mechanism configured to control a rotation of the support platform, a movement of the transport mechanism and an operation of the gripping mechanism.

10. The handling apparatus of claim 9, wherein the control mechanism comprises a sensor mounted at a tail end of the gripping mechanism and is configured to confirm whether one of the loading stations is loaded with a corresponding one of the objects to be handled and control, based on results of the confirmation, the rotation of the support platform.

11. The handling apparatus of claim 1, wherein the objects to be handled are wafer cassettes.

12. A handling method, using the handling apparatus as claimed in claim 1, comprising:
moving a transport mechanism to an object storage place;
driving, by a driving mechanism, a support platform to rotate in a horizontal plane to allow one of a plurality of loading stations that is loaded with an object to be handled to move to a location facing the object storage place;
picking up the object from the loading station and placing the object at the object storage place, by a gripping mechanism; and
repeating the above steps to successively transport objects to be handled from the plurality of loading stations to the object storage place.

13. A handling method, using the handling apparatus as claimed in claim 1, comprising:
moving a transport mechanism to an object storage place;
driving, by a driving mechanism, a support platform to rotate in a horizontal plane to allow one of a plurality of loading stations that is loaded with an object to be handled to move to a location facing the object storage place;
picking up the object from the object storage place and placing the object at the loading station, by a gripping mechanism; and
repeating the above steps to successively transport objects to be handled to the plurality of loading stations.

14. The handling method of claim 12, wherein the objects to be handled are wafer cassettes, each of the loading stations is provided with an identification device for identifying an identification mark on a wafer cassette, and when the handling apparatus moves to the object storage place while carrying a target one of the wafer cassettes, one of the loading stations loaded with the target one of the wafer cassettes is identified based on information fed back from the identification device and the driving mechanism drives the support platform to rotate in the horizontal plane so that the loading station loaded with the target one of the wafer cassettes is moved to the place facing the object storage place.
